(19) United States
(12) Patent Application Publication
(10) Pub. No.: US 2012/0163630 A1
(43) Pub. Date: Jun. 28, 2012

(54) AUDIO PROCESSING APPARATUS, AUDIO PROCESSING SYSTEM, AUDIO PROCESSING METHOD

(75) Inventors: Takehide Yano, Hamura-shi (JP); Shuta Ogawa, Kawasaki-shi (JP)

(73) Assignee: KABUSHIKI KAISHA TOSHIBA, Tokyo (JP)

(21) Appl. No.: 13/330,500

(22) Filed: Dec. 19, 2011

(30) Foreign Application Priority Data
Dec. 28, 2010 (JP) P2010-294068

(51) Int. Cl. H03G 3/00

(52) U.S. Cl. 381/107

(57) ABSTRACT

An audio processing apparatus includes a first capture module, a limitation module, a second capture module, and a release module. The first capture module is configured to capture an external input. The limitation module is configured to transmit a sound volume limitation command to at least one external device including an audio output function when the first capture module captures the external input. The second capture module is configured to capture a sound input after the first capture module captured the external input. The release module is configured to transmit, after the second capture module captured the sound input, a release command for the sound volume limitation on the one or more external devices limited by the limitation module at a timing that differs according to the sound input captured by the second capture module.

### CROSS REFERENCE TO RELATED APPLICATION(S)

The present disclosure relates to the subject matters contained in Japanese Patent Application No. 2010-294068 filed on Dec. 28, 2010, which are incorporated herein by reference in its entirety.

### FIELD

Embodiments described herein relate to an audio processing apparatus, an audio processing system and an audio processing method for performing processing according to sound input.

### BACKGROUND

An apparatus input by speech from a user is known that recognizes words included in the input speech, and performs processing according to the input speech.

An apparatus may not be able to perform the processing as intended by a user when the words included in the input speech are falsely recognized.

### BRIEF DESCRIPTION OF THE DRAWINGS

A general configuration that implements the various features of the invention will be described with reference to the drawings. The drawings and the associated descriptions are provided to illustrate embodiments of the invention and should not limit the scope of the invention.

FIG. 1 is a diagram illustrating an example of a mode of use of an audio remote controller, according to an exemplary embodiment.

FIG. 2 is a diagram illustrating an example of a system configuration of an audio remote controller, a display device and an audio device, according to an exemplary embodiment.

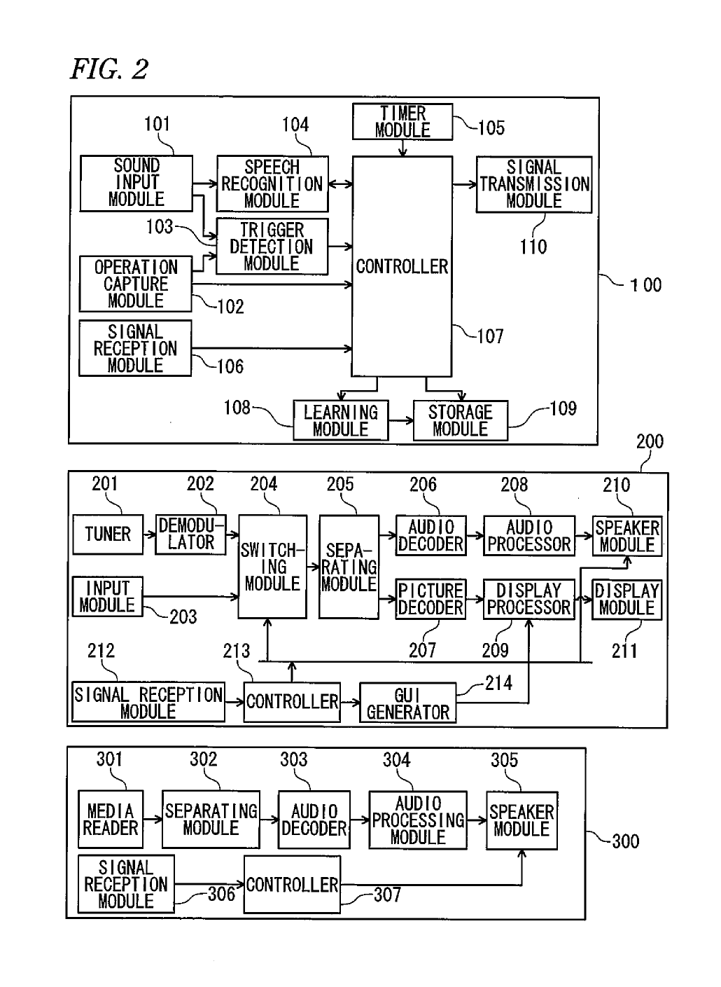

FIGS. 3A to 3D are examples of a database configuration provided to an audio remote controller, according to an exemplary embodiment.

FIG. 4 is a diagram of an example of an input switching screen for display on a display device, according to an exemplary embodiment.

FIG. 5 is an example of a processing sequence by an audio remote controller, a display device and an audio device, according to an exemplary embodiment.

FIG. 6 is an example of processing flow in speech recognition processing by an audio remote controller, according to an exemplary embodiment.

FIG. 7 is an example of processing flow by a display device according to instructions from an audio remote controller, according to an exemplary embodiment.

### DETAILED DESCRIPTION OF THE EMBODIMENTS

According to one embodiment, there is provided an audio processing apparatus including a first capture module, a suppression module, a second capture module, and a release module. The first capture module is configured to capture an external input. The suppression module is configured to transmit a sound volume suppression command to at least one external device including an audio output function when the first capture module captures the external input. The second capture module is configured to capture a sound input after the first capture module captured the external input. The release module is configured to transmit, after the second capture module captured the sound input, a release command for the sound volume suppression on the one or more external devices suppressed by the suppression module at a timing that differs according to the sound input captured by the second capture module.

Explanation now follows of an exemplary embodiment, with reference to the drawings.

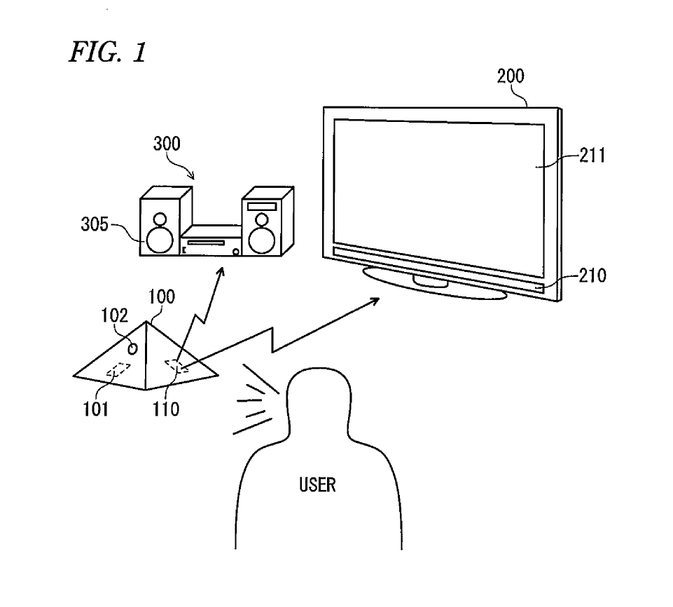

FIG. 1 is a diagram illustrating an example of a mode of use of a data processing system according to an exemplary embodiment. The data processing system includes, for example, a speech recognition remote controller (referred to below as an audio remote controller) 100, a display device 200, and an audio device 300.

The audio remote controller 100 is provided with a sound input module 101, an operation capture module 102, a speech recognition module 104 and a signal transmission module 110. The voice remote controller 100 has functionality as a remote controller for operating the display device 200. The sound input module 101 is, for example, an audio input device such as a microphone, and is input with the speech spoken by or sounds produced by a user. The speech recognition module 104 analyses the speech that was input to the sound input module 101 and determines words included in the input speech. The signal transmission module 110 transmits an operation signal corresponding to the determined words to the display device 200 using wireless or infrared transmission. When, for example, the operation capture module 102 has received an operation input, or the sound input module 101 has been input with a trigger sound, such as a clap, the signal transmission module 110 transmits a signal indicating a suppression of sound volume to the display device 200 and/or to the audio device 300.

The display device 200 includes a speaker module 210, a display module 211 and a signal reception module 212, and has functionality for reproducing (decoding) contents. The speaker module 210 outputs sound of reproduced contents. The display module 211 displays pictures of reproduced contents. The signal reception module 212 receives various operation signals (commands), transmitted from the audio remote controller 100, such as sound volume operation signals. The display device 200 performs processing according to the received operation signals.

The audio device 300 includes a speaker module 305 and a signal reception module 306, and has functionality for reproducing audio contents from an Optical Disc Drive (ODD) or stored on a storage device. The speaker module 305 outputs sound for reproduced audio contents. The signal reception module 306 receives signals such as a sound volume control signal transmitted from the audio remote controller 100. The audio device 300 performs processing according to the received operation signal.

In the data processing system of the present exemplary embodiment, when in receipt of a trigger input from a user the audio remote controller 100 transmits a signal instructing sound volume control to a device for audio output of sound, such as the display device 200 or the audio device 300. The audio remote controller 100 thereby suppresses sound output in the periphery of the audio remote controller 100, accordingly suppressing the intrusion of noise in the sound input other than the speech of a user when performing speech recognition on input speech spoken by a user, so as to suppress misrecognition of speech.

Explanation follows regarding an example of a configuration of a system of the audio remote controller 100, the display device 200 and the audio device 300.

Explanation is first given regarding the audio remote controller 100. The audio remote controller 100 includes the sound input module 101, the operation capture module 102, a trigger detection module 103, the speech recognition module 104, a timer module 105, a signal reception module 106, a controller 107, a learning module 108, a storage module 109 and the signal transmission module 110.

Audio from speech or sound generated by a user is input to the sound input module 101. Examples of such input sound included speech (words) instructing an operation to be performed on the display device 200 and the sound of a clap. The sound input module 101 outputs the input audio to both the trigger detection module 103 and the speech recognition module 104.

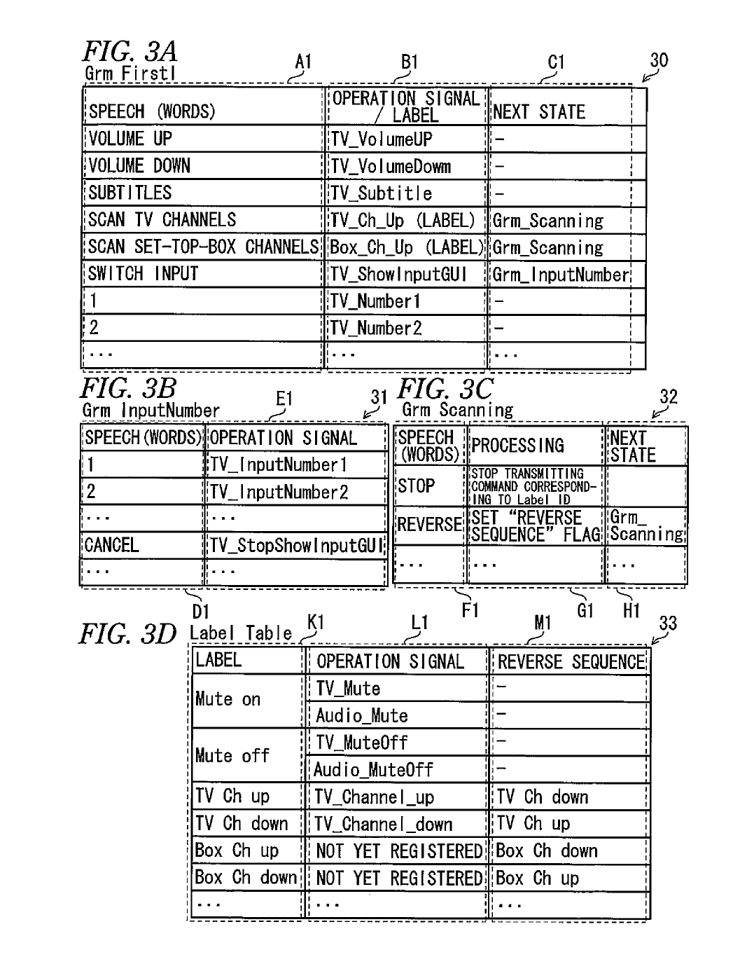

The operation capture module 102 is, for example, one or more buttons provided on the case of the audio remote controller 100, and captures a speech recognition start operation, or a signal-add operation for a specific label or specific speech (words). On receipt of a speech recognition start operation, the operation capture module 102 outputs notification to the trigger detection module 103. On receipt of a signal-add operation the operation capture module 102 outputs a signal-add notification to the controller 107. Details regarding the labels are described later with reference to FIG. 3.

The trigger detection module 103 detects for a trigger sound in the audio input from the sound input module 101. The trigger detection module 103, for example, detects for a specific number of claps of a specific volume or greater as the trigger sound. The trigger detection module 103 outputs a trigger detection notification to the controller 107 when a trigger sound is detected. The trigger detection module 103 further outputs a trigger detection notification to the controller 107 when the trigger detection module 103 receives notification from the operation capture module 102.

The speech recognition module 104 analyses audio input from the sound input module 101, and determines whether speech (words) are included in the audio. The speech recognition module 104 performs this determination based on one database from plural database stored in the storage module 109. The respective databases are databases stored with operation signals that can be transmitted by the audio remote controller 100, speech (words) corresponding to operation signals, and sound characteristic features for reference use, with these data elements associated with each other. Further details regarding these databases are given later with reference to FIGS. 3A to 3D.

The speech recognition module 104 then determines as input speech (words) any speech (words) associated with reference sound characteristic features, from out of reference sound characteristic features stored in the database, showing a degree of matching of a specific threshold value or greater against the input sound characteristic features. The speech recognition module 104 then outputs to the controller 107 a notification indicating whether or not the input audio has speech (words) corresponding to an operation signal. The speech recognition module 104 either starts or ends speech recognition according to instructions from the controller 107.

The timer module 105 starts or resets a timer according to instruction from the controller 107. The signal reception module 106 has functionality for receiving an operation signal transmitted from a remote controller other than the audio remote controller 100. Examples of such other remote controls include a remote controller for transmitting an operation signal corresponding to the display device 200 for use by the display device 200, a remote controller for transmitting an operation signal corresponding to the audio device 300 for use by the audio device 300. Configuration may be made such that an operation signal is received from a device for transmitting an operation signal for use by a set top box, not shown in the drawings. The signal reception module 106 is for, for example, receiving an operation signal from another remote controller when signal learning for the operation signals of the other remote controller. The signal reception module 106 outputs the received signal to the learning module 108 through the controller 107.

The controller 107 has functionality for controlling each configuration of the audio remote controller 100. The controller 107, for example, controls to start or finish speech recognition (discrimination) processing by the speech recognition module 104, to select the database to be employed in speech recognition processing by the speech recognition module 104, and to control transmission of operation signals by the signal transmission module 110. Further explanation regarding control for speech recognition starting/finishing, database selection, and operation signal transmission is given later, with reference to FIGS. 3A to FIG. 6.

The learning module 108 has functionality for learning operation signals for a device not pre-registered in the storage module 109, and for then storing the learnt operation signals in the storage module 109. When the learning module 108 is input from the operation capture module 102 with a signal-add notification for a specific label or speech (words), the learning module 108 requests a user to transmit the operation signal to be added to the signal reception module 106. The learning module 108 requests a user through, for example, a display module or audio output module, not shown in the drawings. The learning module 108 associates the operation signal received by the signal reception module 106 with the respective label or speech (words), and stores the association in the storage module 109 in a table format such as the one shown in FIGS. 3A to 3D. Namely, the learning module 108 stores in the storage module 109 a signal for suppressing sound volume, such as muting, not previously registered in the storage module 109, or a signal for releasing the sound volume suppression. In other words the learning module 108 permits a user to associate audio input to the sound input module 101 with an operation signal not previously registered in the audio remote controller 100 received by the signal reception module 106.

The learning module 108 can learn also operation signals other than operation signals related to sound volume suppression, such as, for example, operation signals for instructing channel change, and store the learnt operation signal in the storage module 109.

The storage module 109 is stored with a database for use in discrimination of audio input to the sound input module 101. As described above, the respective databases are databases stored with operation signals that can be transmitted by the audio remote controller 100, speech (words) corresponding to the operation signals, and sound characteristic features for reference use, with these data elements stored associated with each other. Further details regarding these databases are given later with reference to FIGS. 3A to 3D.

The signal transmission module 110 transmits each of the various operation signals to the display device 200 and the audio device 300.

Explanation follows regarding the display device 200. The display device 200 includes a tuner 201, a demodulator 202, an input module 203, a switching module 204, a separating module 205, an audio decoder 206, a picture decoder 207, an audio processor 208, a display processor 209, the speaker module 210, the display module 211, the signal reception module 212, a controller 213 and a GUI generator 214.

The tuner 201 receives, for example, a digital satellite television broadcast signal received with an antenna for Broadcasting Satellite/Communication Satellite (BS/CS) digital broadcast reception (not shown in the drawings), and/or a digital terrestrial television broadcast signal received with an antenna for terrestrial broadcast reception (not shown in the drawings).

The demodulator 202 employs, for example, a Phase Shift Keying (PSK) method or a Orthogonal Frequency Division Multiplexing (OFDM) method to demodulate the broadcast signal received by the tuner 201 into data of Transport Stream (TS) format. The demodulated data is then output by the demodulator 202 to the switching module 204.

The input module 203 is an external input terminal, such as a High Definition Multimedia Interface (HDMI). The input module 203 is input with picture and audio data output from an external device connected to the input module 203, and outputs the input data to the switching module 204.

The switching module 204 outputs to the separating module 205 data input from the module corresponding to an instruction from the controller 213, from out of the picture and audio data input from the modules of the demodulator 202 and the input module 203.

The separating module 205 separates the input data into picture data and audio data. The separating module 205 then outputs the audio data to the audio decoder 206 and the picture data to the picture decoder 207.

The audio decoder 206 decodes the audio data input from the separating module 205 and outputs the decoded audio data to the audio processor 208. The picture decoder 207 decodes the picture data input from the separating module 205 and outputs the decoded picture data to the display processor 209. The picture decoder 207 is capable of decoding both video data for a main picture and also for a sub-picture such as picture data for sub-titles, and capable of switching between execution or halting of sub-picture decoding according to instruction from the controller 213.

The audio processor 208 converts decoded audio data from the audio decoder 206 into an audio signal of a format capable of output from an audio output device such as speakers. The audio processor 208 outputs the converted audio signal to the speaker module 210.

The display processor 209 converts the picture data decoded by the picture decoder 207 and the picture data of screens generated by the GUI generator 214 into a picture signal of a format capable of display on a display device, such as a display. The display processor 209 then outputs the picture signal to the display module 211. When the decoded data of both video data and sub-picture data is input from the picture decoder 207, the display processor 209 generates a picture signal of a format in which the two pictures are overlaid on each other.

The speaker module 210 outputs sound of the audio signal input from the audio processor 208 at a sound volume according to instruction from the controller 213. The display module 211 displays a picture of the picture signal input from the display processor 209.

The signal reception module 212 receives operation signals from the audio remote controller 100 for output to the controller 213. The controller 213 controls each of the modules configuring the display device 200 according to operation signals that are input. For example, when in receipt of a signal related to sound volume control, the controller 213 controls the speaker module 210 to control the sound volume output, and when in receipt of a signal related to subtitle display control, the controller 213 controls the picture decoder 207 to control the decoding and output of subtitle data. When in receipt of a signal related to channel control, the controller 213 controls the tuner 201 to control the reception channel, when in receipt of an input switching GUI display signal, the controller 213 instructs the GUI generator 214 to generate a GUI, and when in receipt of a signal related to input switching, the controller 213 controls the switching module 204 to switch over the picture input source.

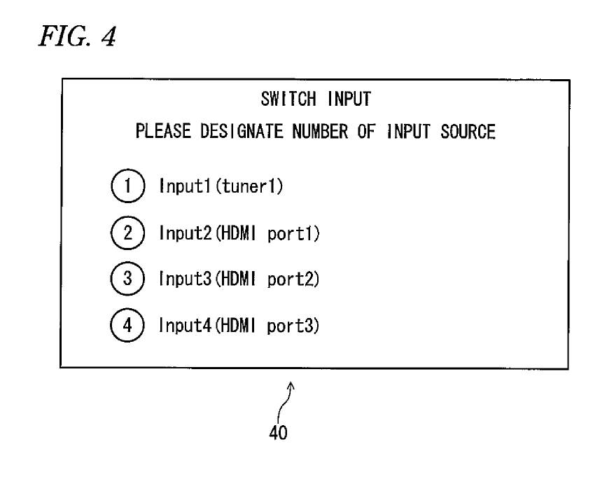

The GUI generator 214 generates a GUI according to instruction from the controller 213, and outputs the generated GUI picture data to the display processor 209. Further explanation regarding the screens generated by the GUI generator 214 is given later with reference to FIG. 4.

Explanation follows regarding the audio device 300. The audio device 300 includes a media reader 301, a separating module 302, an audio decoder 303, an audio processing module 304, the speaker module 305, the signal reception module 306, and a controller 307.

The media reader 301 has functionality for reading out data such as audio data from a storage medium, such as an optical disc or a flash device. The media reader 301 outputs the read data to the separating module 302. The separating module 302 separates out audio data from the input data, and outputs the separated audio data to the audio decoder 303. The audio decoder 303 decodes the input encoded data, and the decoded data is converted by the audio processing module 304 into an audio signal for use by a speaker device. The speaker module 305 outputs sound according to the audio signal at a sound volume corresponding to instruction from the controller 307.

The signal reception module 306 receives operation signals from the audio remote controller 100. The controller 307 controls each of the modules configuring the audio device 300 according to signals, out of the operation signals received by the signal reception module 306, the controller 307 is able to interpret as being operation signals for the audio device 300. Hence when the signal reception module 306 is in receipt of a sound volume operation signal corresponding to the audio device 300, the controller 307 controls the speaker module 305 according to the signal so as to adjust the output sound volume.

Explanation follows regarding an example of a configuration of databases for use in operation signal transmission stored in the storage module 109 of the audio remote controller 100, with reference to FIGS. 3A to 3D.

FIGS. 3A, 3B and 3C illustrate examples of a database configuration of associated speech (words) and operation signals.

“Grm_First” in FIG. 3A is an example configuration of a database employed in speech recognition when the audio remote controller 100 has detected a trigger for starting speech recognition. Storage in database 30 is in a speech (words) field A1, a control signal field B1 and a next state field C1. The speech (words) field A1 is a field storing speech (words) that are candidates for determining a match to speech (words) input to the audio remote controller 100. Sound characteristic features for reference use are associated with each of the respective speech (words) (sound characteristic features are not shown in the drawings).

Operation signals or label IDs corresponding to speech (words) are stored in the control signal field B1. When the audio remote controller 100 discriminates input of any of the speech (words) from the speech (words) field A1, the audio remote controller 100 transmits the operation signal corresponding to that speech to the display device 200. Specific operation signals are associated with the label IDs, and when conditions set for each of the label IDs are satisfied, the audio remote controller 100 transmits the operation signal corresponding to that ID.

The next state field C1 is stored with names of databases of speech (words) for corresponding. When the audio remote controller 100 discriminates any input speech (words) stored in the database corresponding speech (words) against database names, the audio remote controller 100 then starts speech recognition using the corresponding database name. The audio remote controller 100 ends speech recognition when there is no stored database name corresponding to the input speech (words).

The speech (words) field A1 of the database 30 is stored with speech (words) of, for example, “volume up”, “volume down”, “sub-titles”, “scan TV channels”, “scan set-top-box channels”, “switch input”, “1”, “2” etc. Namely, when the database 30 is set as the database for use in speech recognition and the audio remote controller 100 has discriminated that speech input to the audio remote controller 100 is “volume up”, the audio remote controller 100 transmits an operation signal “TV_VolumeUp”. “TV_VolumeUp” is an operation signal instructing the display device 200 to increase the output sound volume.

Similarly, when the audio remote controller 100 determines that speech (words) of “volume down”, “subtitles”, “1” or “2” have been input, the audio remote controller 100 transmits respective operation signals of “TV_VolumeDown”, “TV_Subtitle”, “TV_Number1” or “TV_Number2”. These signals are signals instructing the display device 200 to reduce the sound volume, switch the subtitles ON/OFF, display Channel 1, or display Channel 2, respectively.

When the audio remote controller 100 determines that speech (words) of “scan TV channels” or “scan set-top-box channels” have been input, the audio remote controller 100 respectively performs processing corresponding to the label IDs “TV Ch Up” or “Box Ch Up”, as well as setting the database for use in speech recognition as the database “Grm_Scanning”. Further details regarding the label IDs “TV Ch Up” or “Box Ch Up” and the database “Grm_Scanning” are given later.

When speech (words) of “switch input” is input, the audio remote controller 100 transmits an operation signal “TV_ShowInputGUI” and sets the database for use in speech recognition as “Grm_InputNumber”. “TV_ShowInputGUI” is a signal instructing the display device 200 to display an input switching screen.

Explanation follows regarding an example of a configuration of the database “Grm_InputNumber”, with reference to FIG. 3B.

Database 31 is an example of a database configuration for use by the audio remote controller 100 in speech recognition when the audio remote controller 100 has been input with speech (words) “switch input”. Storage in the database 31 is in a speech (words) field D1 and an operation signal field E1. The speech (words) field D1 is a field in which speech (words) are stored of candidates for discriminating matches against speech (words) input to the audio remote controller 100. Sound characteristic features for use as references are associated with the respective speech (words) (sound characteristic features are not shown in the drawings).

The operation signal field E1 is stored with operation signals corresponding to speech (words). When the audio remote controller 100 has discriminated that a speech (words) included in the speech (words) field D1 has been input, the audio remote controller 100 transmits the operation signal corresponding to that speech (words) to the display device 200.

The speech (words) field D1 of the database 31 is also stored with, for example, speech (words) for numbers such as “1”, “2” etc., and speech (words) such as “cancel”. Namely, when the database 31 is set as the database for use in speech recognition and the audio remote controller 100 has discriminated input of speech (words) for a number such as “1”, “2” etc., the audio remote controller 100 transmits the respective operation signal “TV_InputNumber1” or “TV_InputNumber2”. These signals are operation signals instructing the input source for picture display and audio output by the display device 200.

Explanation follows regarding a configuration example of the database “Grm_Scanning”, with reference to FIG. 3C.

Database 32 is an example configuration of a database for use in speech recognition when the audio remote controller 100 has set “Grm_Scanning” as the database. Storage in the database 32 is in a speech (words) field F1, a processing field G1 and a next state field H1. The speech (words) field F1 is stored with speech (words) of candidates for speech (words) input to the audio remote controller 100, and reference sound characteristic features are associated with the respective speech (words).

The processing field G1 is stored with processing contents corresponding to speech (words). When the audio remote controller 100 has discriminated that speech (words) from the processing field G1 has been input, the audio remote controller 100 performs processing corresponding to that speech (words).

The next state field H1 is stored with a database name corresponding to the speech (words). When the audio remote controller 100 has discriminated a given speech (words) has been input and there is a database name stored corresponding to the speech (words), the audio remote controller 100 starts speech recognition using the database corresponding to the database name. However, the audio remote controller 100 ends speech recognition when there is no database name stored corresponding to the input speech (words) in the next state field H1.

Namely, when the audio remote controller 100 has discriminated that the speech “stop” has been input, the audio remote controller 100 stops transmitting the signal corresponding to the current label ID and ends speech recognition. When the audio remote controller 100 has discriminated that the speech “reverse” has been input, the audio remote controller 100 sets a flag for “reverse sequence” and then continues with speech recognition.

Explanation follows regarding an example of a data configuration of a “Label Table” for use by the audio remote controller 100, with reference to FIG. 3D. The audio remote controller 100 uses the database 33 and transmits an operation signal when specific conditions are satisfied.

Storage in the database 33 is in a label ID field K1, an operation signal field L1 and a reverse sequence field M1.

The label ID field K1 is stored with IDs, such as “Mute on”, “Mute off”, “TV Ch Up”, “TV Ch down”, “Box Ch Up” and “Box Ch down”. Set conditions are associated with each of the respective IDs. For example, trigger input is set as the condition for “Mute on”, and, for example, a next state not being stored in the next state field corresponding to input speech (words) is set as the condition for “Mute off”. Similarly, obtaining “scan TV channel” as the result of speech recognition is set as the condition corresponding to “TV Ch Up”.

The operation signal field L1 is stored with operation signals corresponding to label IDs. The audio remote controller 100 transmits the operation signal corresponding to the label when the audio remote controller 100 has determined that the conditions associated with the operation signal field L1 have been satisfied. It is possible to add the registration of new signals in the operation signal field L1 using a learning function referred to above. For example, by learning an operation signal equivalent to “Box Ch Up”, a new channel scan function can be performed for a device other than a TV.

The database 33 has, for example, “TV_Mute” and “Audio Mute” associated with the label ID “Mute on”. “TV_Mute” is a signal instructing the display device 200 to suppress output sound volume and “Audio_Mute” is a signal instructing the audio device 300 to suppress output sound volume.

“TV_MuteOff” and “Audio_MuteOff” are, for example, associated with the label ID “Mute off”. These are signals releasing output sound volume suppression that was instructed by the above “TV_Mute” and “Audio_Mute” respectively.

Signals of “TV_Channel_up” and “TV_Channel_down” are associated with “TV Ch Up” and “TV Ch down”, respectively. These signals instruct the display device 200 to move the channel of the broadcast program being displayed either up or down.

Configuration may be made such that these signals are stored in the audio remote controller 100 in advance when the product is shipped, or are stored in the audio remote controller 100 by employing the learning function referred to above. Namely, the audio remote controller 100 can receive and store operation signals corresponding to the display device 200 and the audio device 300, and then the audio remote controller 100 can transmit the stored operation signals according to speech input during speech recognition, or conditions attached to the labels.

Explanation follows regarding examples of an input switching screen for display by the display device 200, with reference to FIG. 4.

Screen 40 is arrayed with port names of input sources and associated numbers. When the display device 200 is input from the audio remote controller 100 with an operation signal instructing input switch, such as “TV_Number1”, while the display device 200 is displaying the screen 40, the display device 200 sets the input source to the input port corresponding to the signal, and the picture and audio data input from the set port is reproduced and output.

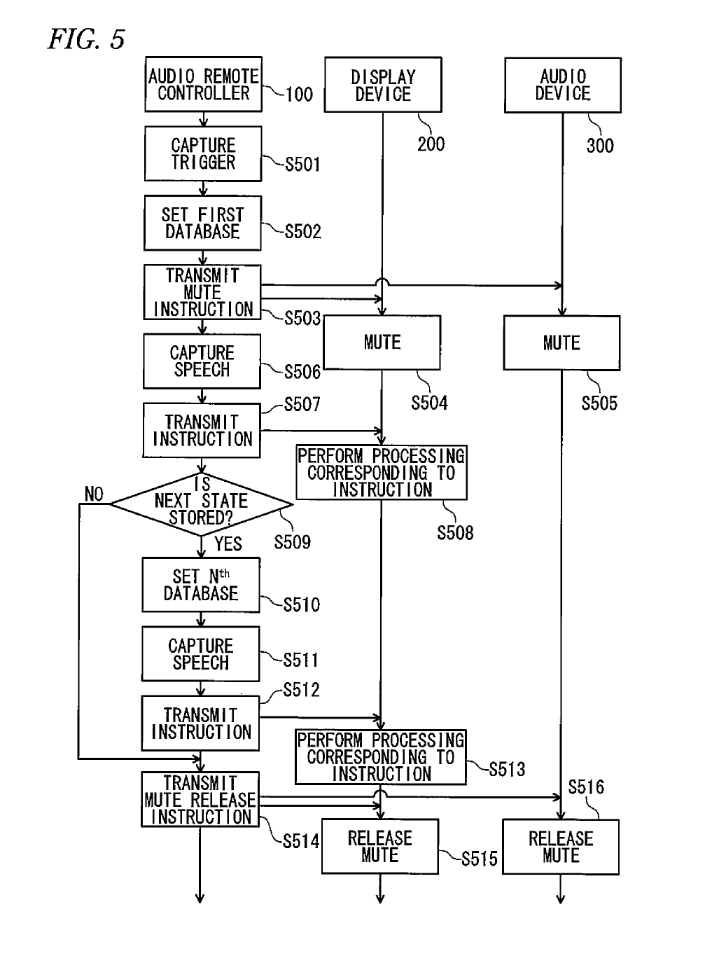

Explanation follows regarding processing sequences of the audio remote controller 100, the display device 200 and the audio device 300, with reference to FIG. 5.

First, when the audio remote controller 100 captures a trigger input for speech recognition start (S501), the audio remote controller 100 sets the database illustrated in FIG. 3A as the database for use in speech recognition (S502), and transmits instruction signals to suppress sound volume (S503). On receipt of the sound suppression signals the display device 200 and the audio device 300 control to suppress output sound volume (S504). Configuration may be made such that during output sound volume suppression, the display device 200 and the audio device 300 mute the sound volume and stop output of sound, or reduce the sound volume to below a specific sound volume.

The audio remote controller 100 then captures speech spoken by a user, and determines whether or not the speech is instructing transmission of an operation signal (S506). The audio remote controller 100 transmits the operation signal corresponding to the input speech (S507), and the display device 200 performs the processing corresponding to the received operation signal (S508).

The audio remote controller 100 determines whether or not a next state is stored in the next state field in the database set for use in speech recognition for the captured speech (S509). When a next state has been set (S509: Yes), the audio remote controller 100 sets the database to the new database (S510), captures speech from a user (S511), and discriminates the captured speech based on the set database. The audio remote controller 100 transmits the operation signal corresponding to the speech discriminated as having been input (S512), and the display device 200 performs processing as instructed by the operation signal (S513).

The audio remote controller 100 then transmits a sound volume suppression release signal (S514), and the display device 200 and the audio device 300 release sound volume suppression when the release signal is received (S515, S516).

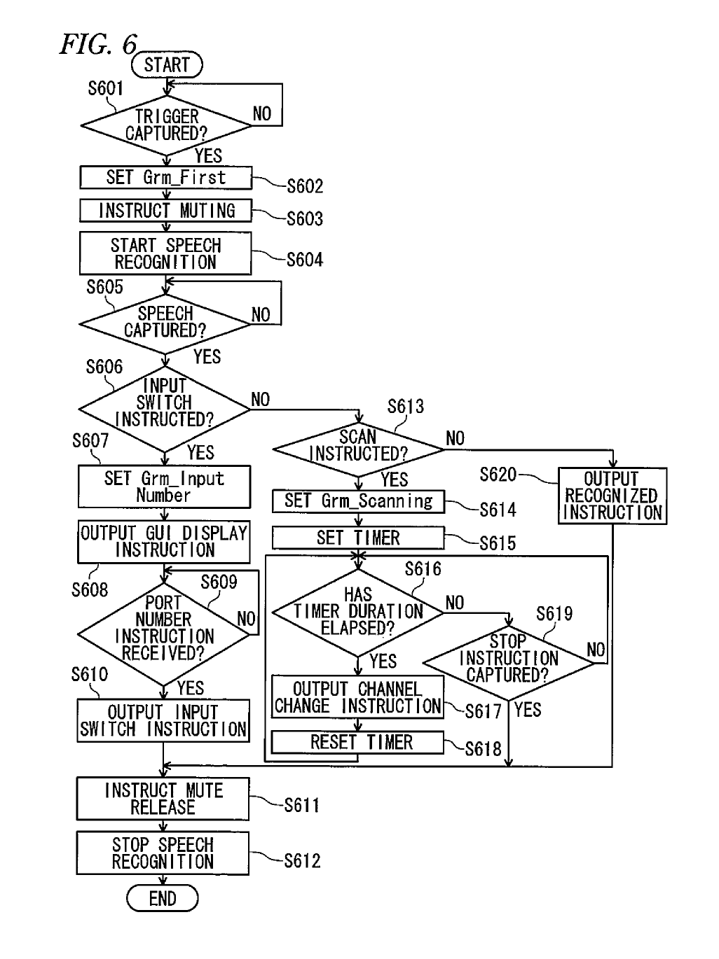

Explanation follows regarding an example of processing flow according to speech recognition processing by the audio remote controller 100, with reference to FIG. 6.

The audio remote controller 100 determines whether or not a trigger to start speech recognition has been captured (S601). As stated above, the audio remote controller 100 may capture a sound, such as a clap sound, or a button input as the trigger. When a trigger is captured, the audio remote controller 100 sets the Grm_First illustrated in FIG. 3A as the reference database for use in speech recognition (S602), then transmits a mute instruction signal corresponding to “Mute on” label of FIG. 3D (S603). The audio remote controller 100 starts speech recognition (S604), and captures speech input (S605). When speech has been input (S605: Yes) the audio remote controller 100 discriminates whether or not the input speech is an instruction signaling an operation to be performed. When speech instructing input switching has been input (S606: Yes), the audio remote controller 100 sets the Grm_InputNumber illustrated in FIG. 3B as the database for use in speech recognition (S607), and transmits a display instruction signal to display an input switching screen to the display device 200 (S608). When the audio remote controller 100 discriminates that speech indicating an input port has been input (S609: Yes), the audio remote controller 100 transmits to the display device 200 a signal to switch input to the discriminated port (S610). Configuration may be made such that the audio remote controller 100 instructs input switching to a specific number port by transmitting the above “TV_InputNumberN” (wherein N is a number). Alternatively the audio remote controller 100 may transmit an operation command indicating at least in identifier, such as a number, so as instruct input switching to the port associated with the identifier at the display device 200 side. The audio remote controller 100 then transmits a mute release signal (S611), stops speech recognition (S612) and completes processing related to speech recognition.

When, however, at S606 the input speech is not speech instructing input switching (S606: No), the audio remote controller 100 discriminates whether or not the input speech is speech instructing channel scanning (S613). When the speech is an instruction to scan channels (S613: Yes), the audio remote controller 100 sets the Grm_Scanning as the reference database (S614), and sets a timer (S615).

The audio remote controller 100 then determines whether or not a specific duration has elapsed (S616), and when the specific duration has elapsed (S616: Yes), transmits a channel change signal to change the channel up or down (S617). The audio remote controller 100 then resets a timer (S618), and determines whether or not the specific duration has once more elapsed (S616). When the timer duration has not yet elapsed (S616: No), the audio remote controller 100 determines whether or not speech for an instruction to stop channel changing has been captured (S619). When speech instructing stopping has been captured (S619: Yes), the audio remote controller 100 performs the processing of S611 and S612, and thereby completes processing related to speech recognition. However, when speech instructing stopping is not received (S619: No), the audio remote controller 100 determines whether or not the specific duration has elapsed (S616). When the audio remote controller 100 captures input of speech to set a reverse sequence flag during S616 to S619, the audio remote controller 100 transmits a channel change instruction at S617 with a different sequence to the channel change instruction output at S617 prior to input of the reverse sequence flag instruction.

However, when the audio remote controller 100 discriminates that speech instructing scanning has not been input at step S613 (S613: No), after the audio remote controller 100 has transmitted the operation signal corresponding to the speech captured at S605 (S620), the audio remote controller 100 performs the processing of S611 and S612, and thereby completes processing related to speech recognition.

According to the above processing flow, the audio remote controller 100 can capture speech input after capture of a trigger, and can switch between continuing or releasing muting of the display device 200 and the audio device 300 depending on speech captured. Namely, the audio remote controller 100 can capture speech after muting the display device 200 and the audio device 300, and can control the release timing of sound volume suppression in the display device 200 and the audio device 300 according to the contents of captured speech even when there is no external input to the audio remote controller 100, such as by user input, after speech capture.

In the above processing flow the audio remote controller 100 starts speech recognition at S604 and halts speech recognition at S612, however there is no limitation to such timings for the start/finish of speech recognition. For example, configuration may be made such that speech recognition is stopped when speech is captured at S605, and speech recognition is restarted when the next reference database is set for speech recognition. Alternatively configuration may be made such that the audio remote controller 100 stops speech recognition and transmits a mute release signal is when no speech input stored in the speech recognition reference database is discriminated as having been input in a specific duration from after starting speech recognition.

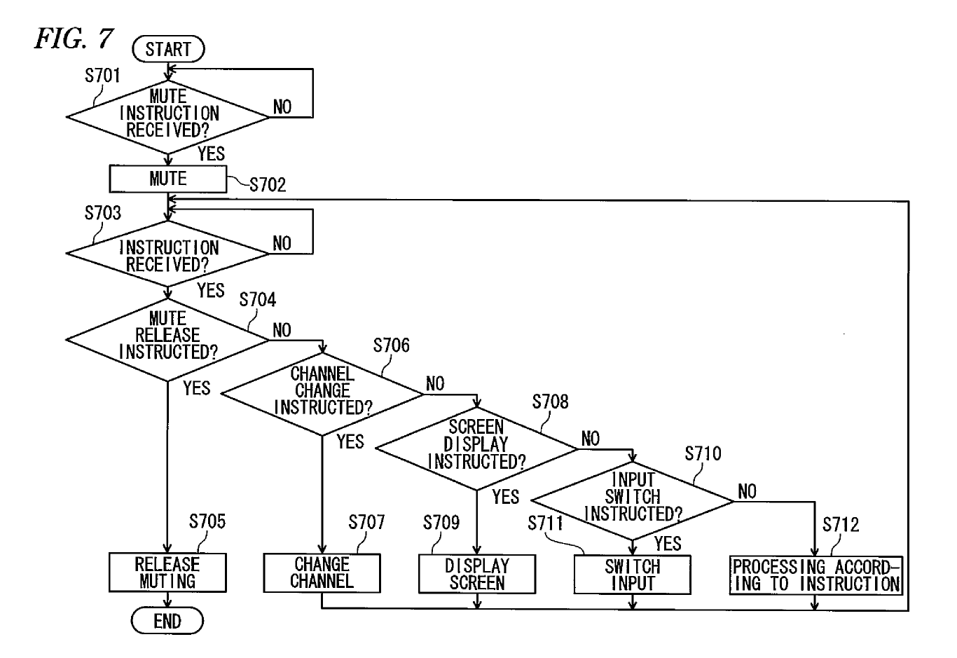

Explanation follows regarding an example of processing flow for sound output by the display device 200, with reference to FIG. 7.

When pictures and sound input to the tuner 201 and the input module 203 is being reproduced and output by the display device 200 and a mute instruction signal is input from the audio remote controller 100 (S701: Yes), the display device 200 stops outputting sound (S702). The display device 200 then waits for receipt of an operation signal from the audio remote controller 100, and processing proceeds to the next step when such a signal is received (S703: Yes). Then the display device 200 releases the suppression of sound volume (S705) when the received signal is a signal instructing mute release (S704: Yes), and the process flow related to sound output is thereby completed.

However, when the received signal is not a mute release signal (S704: No) and the received signal is a channel change signal (S706: Yes), the display device 200 changes the channel according to the received signal (S707) and performs the processing of 5703. However, when the received signal is an input switching screen display signal (S706: No, S708: Yes), the display device 200 displays the input switching screen (S709), and re-performs the processing of S703.

When the received signal is a signal designating an input port for pictures and audio (S708: No, S710: Yes), the display device 200 switches the input port for pictures and audio to the port corresponding to the signal (S711), then re-performs the processing of S703. Configuration may be made such that the display device 200 receives the above “TV_InputNumberN” (wherein N is a number) and switches input to the port expressed in the command, or receives a command expressing at least an identifier and then switches over input to the port corresponding to the identifier.

When the signal received is a signal other than a signal instructing mute release, channel change, input switching screen display or input port (S710: No), the display device 200 performs the processing according to the signal (S712), then re-performs the processing of S703. The display device 200 repeatedly performs the processing of S703, S704, S706 to S712, and releases muting (S705) when a signal instructing mute release is received (S704: Yes), thereby completing processing flow related to sound output.

While various exemplary embodiments have been explained, the exemplary embodiments are merely given as examples and are not intended to limit the scope of embodiments described herein. The exemplary embodiments maybe performed with various modifications within a scope that does not depart from the spirit, and various omissions, substitutions and changes can be made. For example, the audio processing device according to embodiments described herein may be configured without the audio remote controller for instructing operation of the display device 200 from externally to the display device 200, and may, for example, by installed within the casing of the display device 200. The audio remote controller of the exemplary embodiments is not limited to one that transmits operation signals to a counterparty device of a display device. For example, a reception device may be provided to a tuner, received picture and audio data decoded and output to a display/speaker device, and the operation signals transmitted to a set top box that causes pictures and sound to be output by the display/speaker device. Similarly the audio remote controller can learn operation signals for set top box use. Such exemplary embodiments and modifications thereof are included in the scope of embodiments described herein as recited in the claims and their equivalents.

What is claimed is:

1. An audio processing apparatus comprising:
a first capture module configured to capture an external input;
a limitation module configured to transmit a sound volume limitation command to at least one external device comprising an audio output function, when the first capture module captures the external input;
a second capture module configured to capture a sound input after the first capture module captures the external input; and
a release module configured to transmit, after the second capture module captures the sound input, a release command for the sound volume limitation on the one or more external devices, at a timing that differs according to the sound input captured by the second capture module.

2. The audio processing apparatus of claim 1, further comprising an operation controller configured to transmit, to an external device, an operation command based on the sound input captured by the second capture module, when the second capture module captures the sound input.

3. The audio processing apparatus of claim 1, further comprising an operation controller configured to, at regular time intervals, transmit to an external device, configured to output a picture of a television program, a change command to change the television program to be output, when the second capture module captures a first sound.

4. The audio processing apparatus of claim 3,
wherein the operation controller is configured to stop the transmission of the change command when the second capture module captures a second sound after capturing the first sound; and
wherein the release module is configured to transmit the release command when the second capture module captures the second sound.

5. The audio processing apparatus of claim 3, wherein the operation controller is configured to transmit the change command to change programs to be output in a first sequence when the second capture module captures the first sound, and to transmit the change command to change programs to be output in a second sequence when the second capture module captures a third sound.

6. The audio processing apparatus of claim 2, wherein the operation controller is configured to transmit the operation command the external device to perform a first operation when the second capture module captures a first sound, to perform a second operation when the second capture module captures a second sound, and to perform a third operation different from the first operation when the second capture module captures the second sound after capturing the first sound.

7. The audio processing apparatus of claim 6, wherein the operation controller is configured to transmit to the external device:
the operation command to output a picture of a program based on the first sound, when the second capture module has captured the first sound,
the operation command to output a first screen when the second capture module captures the second sound, and
the operation command to perform input switching based on the first sound when the second capture module captures the first sound after capturing the second sound.

8. The audio processing apparatus of claim 2, further comprising:
a receiver configured to receive an operation signal transmitted from a signal transmission device configured to transmit an operation signal corresponding to the external device; and
a storage module configured to store the received operation signal,
wherein the operation controller is configured to transmit to the external device the operation signal stored in the storage module, the operation signal corresponding to the sound input captured by the second capture module.

9. The audio processing apparatus of claim 8, further comprising a permitting module configured to permit a user to associate the received operation signal to a sound captured by the second capture module,
wherein the operation control module is configured to transmit to the external device the operation signal associated with the sound captured by the second capture module.

10. An audio processing system comprising a reception apparatus and an audio processing apparatus,
wherein the reception apparatus comprises:
a receiver configured to receive picture data and audio data; and
a controller configured to control a display device to display a picture of the received picture data and to control an audio output device to output sound of the received audio data, and
wherein the audio processing apparatus comprises:
a first capture module configured to capture an external input;
a limitation module configured to limit sound volume of the sound output by the audio output device when the external input is captured;
a second capture module configured to capture a sound input after the first capture module captured the external input; and
a release module configured to transmit a release command for the sound volume limitation on the audio output device at a timing that differs according to the sound input captured by the second capture module.

11. An audio processing method comprising:
capturing an external input;
transmitting a sound volume limitation command, to at least one external device comprising an audio output function, when the external input is captured;
capturing a sound input after the external input is captured;
transmitting a release command for the limited sound volume of the one or more external devices at a timing that differs according to the captured sound input.
